(19) United States
(12) Patent Application Publication
(10) Pub. No.: US 2012/0061658 A1
(43) Pub. Date: Mar. 15, 2012

(54) STRUCTURAL TEMPLATING FOR ORGANIC ELECTRONIC DEVICES HAVING AN ORGANIC FILM WITH LONG RANGE ORDER

(75) Inventors: Stephen R. Forrest, Ann Arbor, MI (US); Richard R. Lunt, Ann Arbor, MI (US); Stephane Kena-Cohen, London (GB); Brian Einstein Lassiter, Ypsilanti, MI (US)

(73) Assignee: The Regents of the University of Michigan, Ann Arbor, MI (US)

(21) Appl. No.: 13/319,932

(22) PCT Filed: Jun. 3, 2010
(86) PCT No.: PCT/US10/37334

§ 371 Date: Nov. 10, 2011

Related U.S. Application Data
(60) Provisional application No. 61/183,598, filed on Jun. 3, 2009.

(51) Int. Cl. H01L 51/46; H01L 51/56; H01L 51/54; H01L 51/48

(52) U.S. Cl. 257/40; 438/82; 438/46; 257/E51.026

(57) ABSTRACT

An organic photosensitive device having an organic film with a desired crystalline order includes a first electrode layer and at least one structural templating layer disposed on the first electrode A photoactive region is disposed on the templating layer and includes a donor material and an acceptor material, wherein the donor or the acceptor is templated by the templating layer, and further wherein a majority of the molecules of the templated material are in a non-preferential orientation with respect to the first electrode An organic light emitting device incorporating such organic films includes a first electrode layer, a second electrode layer, at least one structural templating layer disposed between the first and second electrodes, and a functional layer disposed over the templating layer A majority of the molecules of the functional layer are in a non-preferential orientation with respect to the layer below the templating layer

### GOVERNMENT RIGHTS

This invention was made with U.S. Government support under grant number FA-9550-041-0120 awarded by the Air Force Office of Scientific Research. The government has certain rights in the invention.

### TECHNICAL FIELD

The present disclosure relates to organic films for use in organic electronic devices.

### BACKGROUND

In organic electronic devices made with organic thin films, the morphology (e.g., the crystal structure) of the organic films can play a role in determining the electronic and/or optical properties of the device. In many cases, the organic molecules in the films exhibit a pronounced anisotropy, and the orientation of the organic molecules within the film can influence charge carrier mobility. For example, creating crystalline order within an organic film of an organic light emitting device can reduce series resistance, and thereby increase luminous efficiency. In organic photosensitive devices such as organic photovoltaic (OPV) devices, creating crystalline order within an organic film of the photosensitive devices can increase the short-circuit current J_{sc}, and the open-circuit voltage V_{oc}. For example, controlling the molecular crystalline orientation of the donor layer for example can lead to beneficial changes in the frontier energy levels, absorption coefficient, morphology, and exciton diffusion length, resulting in an increase in the PV cell's power conversion efficiency, ηₚ. Furthermore, because crystalline structures are morphologically more stable than amorphous structures, the resulting devices would have the potential for greater long term operational reliability. While it is clear that the crystal structure of the organic molecules in an organic thin film can be an important feature of the devices, it has been difficult to achieve the desired film crystal structure. Thus, there is a need for improved methods for growing an organic film having a desired crystal structure for use in organic electronic devices.

### SUMMARY

The present disclosure provides organic films having a desired film morphology (e.g., molecular orientation, surface roughness, grain size, phase purity, etc.) for use in organic electronic devices. In one embodiment of the present disclosure, an organic photosensitive device incorporating such organic films is disclosed. The organic photosensitive device comprises a first electrode layer and at least one structural templating layer disposed on the first electrode layer. A photoactive region is disposed on the at least one structural templating layer where the photoactive region comprises a donor material and an acceptor material, wherein the donor material or the acceptor material is templated by the at least one structural templating layer and thus having an ordered molecular arrangement, and further wherein at least a majority of the molecules of the templated material are in a non-preferential orientation with respect to the first electrode layer. The device further comprises a second electrode layer disposed over the photoactive region. A method for making the organic photosensitive device is also disclosed.

In one embodiment, an organic light emitting device is disclosed wherein the device comprises a first electrode layer, a second electrode layer, at least one structural templating layer disposed between the first and second electrodes, and a functional layer disposed over the at least one structural templating layer. The functional layer has its molecules in an ordered molecular arrangement, wherein at least a majority of the molecules of the functional layer are in a non-preferential orientation with respect to the layer immediately below the at least one structural templating layer. A method for making such organic light emitting device is also disclosed.

In another embodiment, an organic light emitting device is disclosed wherein the device comprises a first electrode layer and at least one structural templating layer disposed over the first electrode layer. An organic emissive layer is disposed over the at least one structural templating layer. The organic emissive layer can be a neat layer or can comprise a host material doped with a dopant material. The device further comprises a second electrode layer disposed over the organic emissive layer, wherein the dopant material has an ordered molecular arrangement within the organic emissive layer, and further wherein at least a majority of the dopant molecules are in a non-preferential orientation with respect to the first electrode layer. A method for making the organic light emitting device is also disclosed.

In another embodiment, the present disclosure provides a method for making an organic electronic device having an organic film with the desired film morphology. The method comprises growing an organic film on a template substrate by depositing organic molecules onto the template substrate, and transferring the organic film to a host substrate for an organic electronic device. In some cases, the organic film may be cold-welded to the host substrate.

In another embodiment, the present disclosure provides an organic electronic device comprising a host substrate and an organic film disposed directly on the host substrate. The organic film is formed of organic molecules in an ordered arrangement and at least a majority of the organic molecules within the organic film are in a non-preferential orientation with respect to the host substrate. In some cases, the organic film may have a thickness of 300 Å or greater, with at least a majority of the organic molecules throughout the thickness of the organic film being in the non-preferential orientation.

### BRIEF DESCRIPTION OF THE DRAWINGS

FIGS. 1A-1F show an example of how a method of the present disclosure may be implemented to make an organic electronic device.

FIGS. 2A and 2B schematically illustrate an example of how an organic film grown on a template substrate may differ from an organic film that is grown on a host substrate.

FIGS. 3A and 3B schematically illustrate another example of how an organic film grown on a template substrate may differ from an organic film grown on a host substrate.

FIG. 4A shows x-ray diffraction spectra obtained for various pentacene films grown on a KBr substrate. FIGS. 4B and 4C show RHEED patterns and cross-polarized optical microscopic images for two of the pentacene films.

FIGS. 5A and 5B show RHEED patterns for C₆₀ films grown directly on an ordered pentacene film. FIG. 5C shows x-ray diffraction spectra obtained for the C₆₀ films.

FIG. 6A shows the molecular structure of di-indenoperylene (DIP). FIG. 6B shows possible unit cell arrangements of DIP molecules in the α-phase and the β-phase.

FIG. 7 shows x-ray diffraction spectra for DIP films grown on quartz and PTCDA.

FIGS. 8A-C show RHEED patterns obtained at different azimuthal angles for a DIP film grown on a KBr substrate.

FIG. 9A shows an atomic force microscopy image of a DIP film grown on a KBr substrate. FIG. 9B shows a cross-polarized optical microscopic image of the DIP film.

FIGS. 10A-D show atomic force microscopy images of the surface of DIP films grown on various substrates.

FIG. 11 shows x-ray diffraction spectra for films made of Pt(pq)(acac): platinum (2-[2′pyridyl] quinoxaline)(acetylacetonate).

FIG. 12(a) shows x-ray diffraction plots of separate layers of PTCDA, CuPc, DIP, and combinations of these layers.

FIG. 12(b) is a schematic representation of the (200) orientation of CuPc molecules.

FIG. 12(c) is a schematic representation of the (312) orientation of CuPc molecules.

FIG. 13(a) shows ultraviolet photoelectron spectroscopy measurements of PTCDA, CuPc, and CuPc on PTCDA template layer.

FIG. 13(b) is a schematic energy diagram of measured values for the HOMO of PTCDA, DIP, and CuPc films in units of eV.

FIG. 14(a)-(d) are atomic force microscope images of the CuPc film grown directly on ITO (FIG. 14(a)), CuPc film grown on a PTCDA template film (FIG. 14(b)), CuPc film grown on a DIP template film (FIG. 14(c)), and CuPc film grown on a multilayered template film DIP/PTCDA (FIG. 14(d)).

FIG. 15(a) shows absorption plots (lines) and EQE plots (symbols) for sample OPV devices.

FIG. 15(b) is a plot of IQE change from Device (III) to Device (IV).

FIG. 16 is a schematic illustration of an organic photosensitive device according to an embodiment.

FIG. 17 shows x-ray diffraction spectra for the following films deposited on Si: PTCDA (5 nm); coronene (50 nm)/PTCDA (5 nm); CuPc (50 nm)/coronene (5 nm)/PTCDA (5 nm); coronene (50 nm); CuPc (50 nm)/coronene (50 nm).

FIG. 18 is a schematic illustration of an organic light emitting device according to another embodiment.

FIG. 19 shows x-ray diffraction intensity plots for a film of ClAlPc deposited on ITO only and on a structural templating layer of PTCDA on ITO.

FIG. 20(a) shows x-ray diffraction intensity plot for NPD.

FIG. 20(b) shows x-ray diffraction intensity plots for a film of C₆₀ vapor deposited on crystalline NPD and on ITO.

FIGS. 21(a) and (b) are schematic illustrations of the crystal structure orientations of NPD(101) and C₆₀(111), respectively.

### DETAILED DESCRIPTION

The present disclosure provides organic films having a desired film morphology (e.g., molecular arrangement (i.e. crystalline order), surface roughness, grain size, phase purity, etc.) for use in organic electronic devices. In one embodiment, the present disclosure provides organic electronic devices utilizing such organic films. In one embodiment, the present disclosure provides a method for making the organic electronic devices.

As used herein, “structural templating” refers to the effect where a thin layer of an intermediary material deposited on a host substrate where the molecules of the intermediary material exhibit a particular ordered molecular arrangement and causes subsequently deposited second material to follow the underlying ordered molecular arrangement of the intermediary material rather than adopting the second material's intrinsic molecular arrangement that would form preferentially if the second material were deposited on the host substrate. The thin layer of the intermediary material on the host substrate is referred to herein as the “structural templating layer.” By “host substrate,” we mean any component of an organic electronic device suitable for supporting an organic film, such as another organic film (not necessarily one made by the present disclosure), an electrode, or the device substrate (e.g., glass or plastic) on which the device is mounted. By “template substrate,” we mean any substantially flat article or a film/layer of a material upon which an organic film can be deposited/grown in a process in which the organic film deposited/grown thereon is then transferred to a host substrate for an organic electronic device, rather than depositing/growing the organic film material directly on the host substrate.

The organic film may be grown using any suitable deposition technique, including vacuum thermal evaporation, organic vapor phase deposition and organic molecular beam deposition. The template substrate may be made of any material (organic or inorganic) suitable for growing an organic film by such deposition processes. The material for the structural templating layer or the template substrate can be selected for growing an organic film having a desired ordered molecular arrangement for use in an organic electronic device. The invention described herein is not limited to organic films of small molecules only but also applicable to polymer semiconductor material. For organic polymer films, an appropriate deposition technique would include traditional solution processing for polymer deposition where the solvent would not dissolve the underlying structural templating layer. The polymer films can also be deposited using vacuum spray technique. An example of such spray deposition of polymer semiconductors are disclosed in Xiaoliang Mo et al. “Polymer Solar Cell Prepared by a Novel Vacuum Spray Method,” Jpn. J. Appl. Phys. 44 (2005) pp. 656-657.

The molecular arrangement of the organic film can depend upon various factors relating to the choice of the structural templating layer or the template substrate and the growth conditions for the organic film. For example, the orientation of the organic molecules in the film may depend upon the energy of the film structure and the kinetic barriers of the growth process. The energy of the film structure may depend upon the strength of the molecule-substrate interactions versus the strength of the molecule-molecule interactions. The kinetic barriers to the growth process may depend upon the temperature of the template substrate and the rate at which the organic film is grown (or alternatively, the flux of the arriving organic molecules). Thus, various molecular growth orientations may emerge depending upon the choice of the structural templating layer or the template substrate, the nature of the organic molecules used for making the organic film, and/or the film growth conditions. As such, these factors can be selected to promote the growth of an organic film having the desired ordered molecular arrangement.

For organic molecules, structural order may be achieved by epitaxial or quasi-epitaxial growth of the film on the template substrate. The term “quasi-epitaxial” means that the film grows with a distinct orientational alignment between the substrate and film lattices, but lacks short-range commensurability with the substrate. The relationship between the substrate and the incommensurate film lattices involve rotational relationships that are believed to be determined by energetic minima in the van der Waals interactions.

Some types of template substrates, such as metal substrates, are typically wet by the organic molecules. In such cases, the arrangement of the organic molecules may primarily be governed by the molecule-substrate interactions. Other types of substrates, such as metal oxides or ionic substrates (e.g., alkali halides or mica), are typically not wet by organic molecules. In such cases, the arrangement of the organic molecules may primarily be governed by the molecule-molecule interactions. In some cases, the template substrate has an ordered crystalline structure to promote a desired type of ordered molecular arrangement for the film. For example, the template substrate may have a single-crystal surface. In some cases, the template substrate is a structurally ordered organic film (not necessarily one made by the method of the present disclosure).

Examples of organic molecules that can be used with this technique include planar or substantially planar π-conjugated polycyclic aromatic organic molecules. Such organic molecules include acenes (such as anthracene, tetracene, or pentacene) which are planar organic molecules of aromatic rings arranged in a linear fashion, perylenes (such as perylene, diindenoperylene (DIP), or 3,4,9,10-perylene-tetracarboxylicacid-dianhydride (PTCDA)), coronenes (such as hexabenzocoronene), metallo-phthalocyanines (such as zinc-phthalocyanine or vanadyl-phthalocyanine), polyphenylenes (such as hexaphenyl), oligothiophenes (such as α-quaterthiophene or α-hexathiophene).

In an embodiment where the organic film having the desired ordered molecular arrangement is formed on the template substrate that is separate from the optoelectronic device, the organic film is then transferred to the host substrate for an organic electronic device. The organic film may be transferred using any technique suitable for transferring an organic film onto another substrate and detaching the organic film off the template substrate, including cold-welding techniques and various other organic film lift-off techniques known in the art. Cold-welding, although conventionally known for metal-metal bonding, has been described for use with organic films. For example, the cold-welding techniques described in U.S. Pat. No. 6,468,819 (Kim et al.) and U.S. Patent Publ. No. 2005/0170621 (Kim et al.) may be used, both of which are incorporated by reference herein.

In some cases, the cold-welding is performed by placing the organic film in contact with the host substrate and pressing the organic film against the host substrate. With the application of sufficient pressure to decrease the interfacial separation distance below a critical value, the organic film will fuse with the host substrate. In cases where the organic film is not capable of being directly cold-welded to the host substrate, the organic film can be provided with a transfer layer on the surface of the organic film opposite the template substrate. The transfer layer facilitates the transfer of the organic film to the host substrate, and preferably, the transfer layer is made of a material that is capable of being cold-welded to the host substrate. In this case, the transfer layer is placed in contact with the host substrate and pressed against the host substrate to cold-weld the transfer layer to the host substrate. In some cases, the transfer layer and the host substrate are both made of a metal (such as gold or silver), which may be the same or different metals. The thickness of the transfer layer will vary depending upon the particular application. Exemplary transfer layer thicknesses include, but are not limited to, a range of 5-30 nm. The cold-welding process maybe incorporated into a high-throughput manufacturing process for making organic electronic devices, such as roll-to-roll processing on a flexible device substrate.

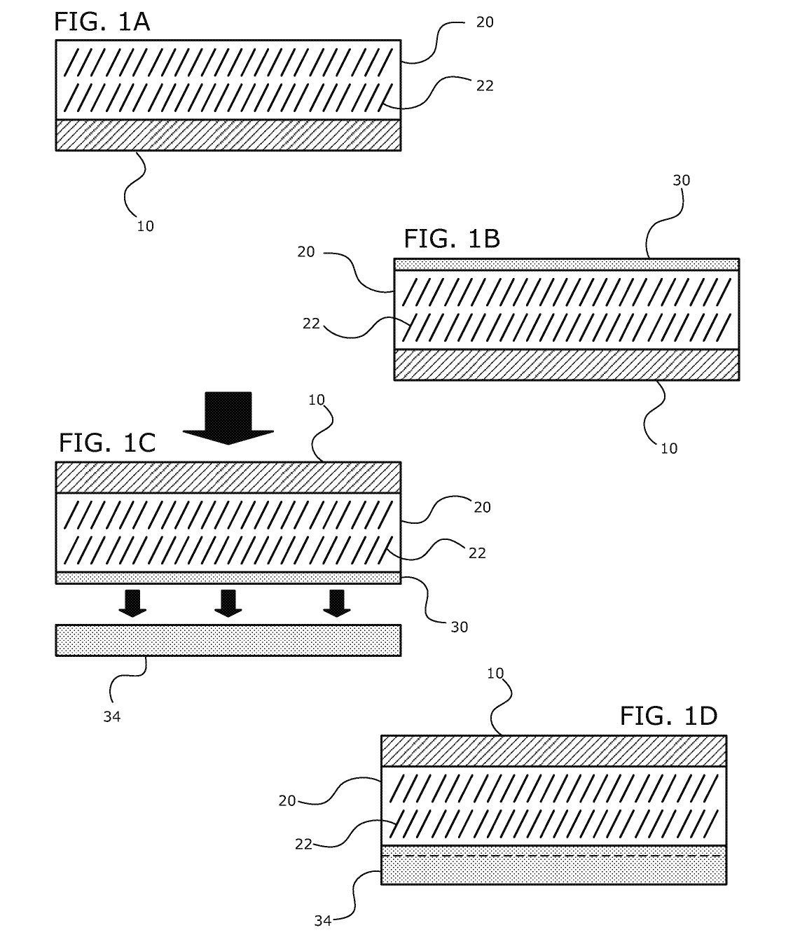

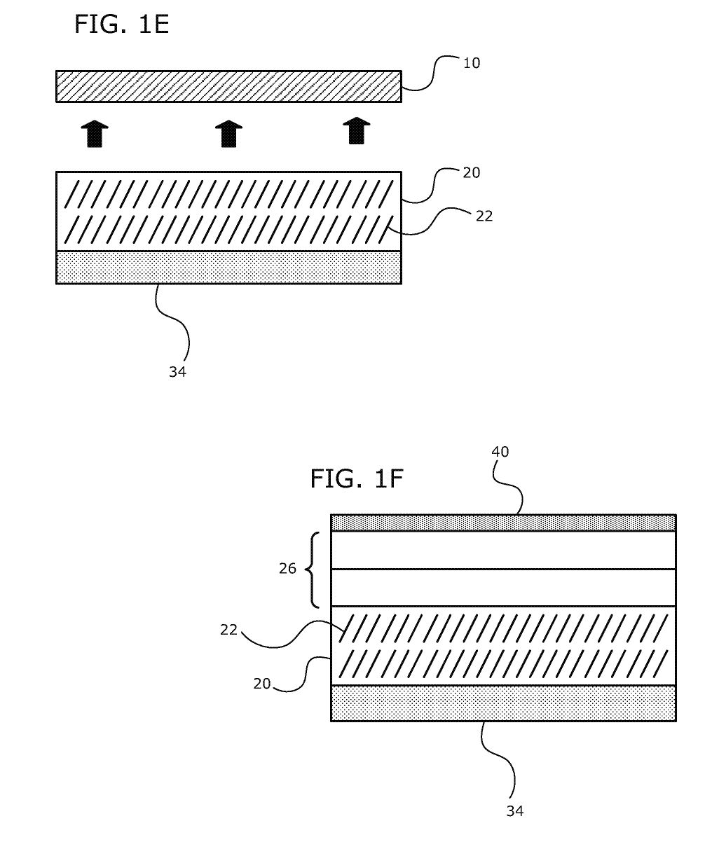

One example of how the method of the present disclosure may be implemented is shown in FIGS. 1A-1F. Referring to FIG. 1A, an organic film 20 is grown quasi-epitaxially onto a silicon oxide template substrate 10. The organic molecules 22 that form organic film 20 have a relatively weak interaction with the template substrate 10. As such, during deposition, the deposited organic molecules 22 become oriented in an upright orientation. Organic film 20 is represented schematically here and is not drawn to scale. For example, to improve clarity, the size of organic molecules 22 are exaggerated and only two monolayers of organic molecules 22 are shown.

Referring to FIG. 1B, after the quasi-epitaxial organic film 20 is grown, a metal transfer layer 30 is deposited on the surface of organic film 20 on the side opposite to template substrate 10. Referring to FIG. 1C, a host substrate 34 is provided, onto which organic film 20 will be transferred. Transfer layer 30 is made to face host substrate 34, and transfer layer 30 is compressed against host substrate 34 to cold-weld transfer layer 30 to host substrate 34. As seen in FIG. 1D, this results in transfer layer 30 being fused to host substrate 34.

As seen in FIG. 1E, template substrate 10 is detached from organic film 20 and lifted off. As a result, the quasi-epitaxially grown organic film 20 has now been transferred to host substrate 34. As seen in FIG. 1F, optionally, other types of functional organic films 26 may be formed over organic film 20. An electrode 40 is then provided on the stack of organic films.

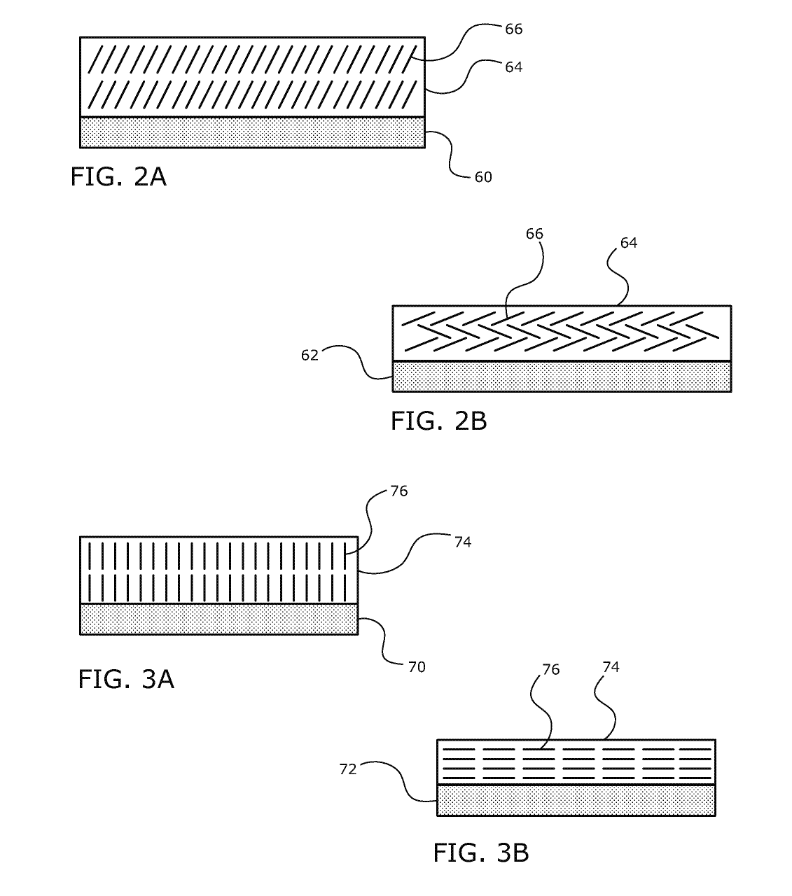

Using the method of the present disclosure, it is possible to provide a host substrate with an organic film having the desired crystal orientation that is different or otherwise not possible if the organic film were grown directly on the host substrate under the relatively mild growth conditions useful for making organic films in organic electronic devices (e.g., substrate temperature in the range of (−25) to 150° C., deposition rate in the range of 0.01 to 10 Å/second, and under pressures in the range of 10⁻¹⁰ torr to 10 torr). FIG. 2A shows an example of how organic molecules 66 may be oriented in an organic film 64 that is grown on a template substrate 60. FIG. 2B shows an example of how the organic molecules 66 would be oriented if the film was to be grown directly on a host substrate 62 under relatively mild growth conditions.

FIG. 3A shows another example of how organic molecules 76 may be oriented to have a desired crystalline order in an organic film 74 that is grown on a template substrate 70. FIG. 3B shows an example of how the organic molecules 76 would be oriented if the film was to be grown directly on a host substrate 72 under relatively mild growth conditions. The method of the present disclosure may also make it possible to provide the host substrate with an organic film having a well-ordered structure that would be otherwise different or not possible if the organic film were grown directly on the host substrate (i.e. such organic film grown directly on the host substrate may be amorphous) under relatively mild growth conditions. Organic films made according to the present disclosure can have long-range crystalline order for film thicknesses of 300 Å or greater. In some cases, organic films made according to the method of the present disclosure have long-range crystalline order for thicknesses in the range of 300 Å-3000 Å. Long-range crystalline order may be maintained through other film thicknesses are also possible. In this disclosure, this will be referred to as having a desired crystalline order or a desired ordered molecular arrangement.

In another embodiment, the present disclosure provides an organic electronic device comprising an organic film, in which the organic film has a long-range crystalline order that is the desired molecular arrangement. The organic film may be made by the above-described method or any other suitable method. The organic electronic device comprises a host substrate onto which the organic film is directly disposed (e.g., by transferring from elsewhere or direct deposition onto the host substrate). Again, the host substrate may be any component of an organic electronic device suitable for supporting an organic film, including other organic films (not necessarily those made by the method of the present disclosure), electrodes, or the device substrate (e.g., glass or plastic) on which the device is mounted. In an embodiment where the host substrate itself is a structural templating substrate or the host substrate is pre-deposited thereon with one or more films of structural templating material, such host substrate can be a part of an optoelectronic device. In that case, the templated organic film does not need to be transferred to a different host substrate.

In certain embodiments, at least a majority of the organic molecules in the templated crystalline organic film have a non-preferential orientation with respect to the host substrate. As used herein, “non-preferential orientation” means that the molecules in the templated organic film have an orientation that is not characteristic of the preferential growth mode if the molecules were to be deposited directly on the host substrate under relatively mild conditions for making organic films in organic electronic devices (i.e., substrate temperature in the range of (−25) to 150° C., deposition rate in the range of 0.01 to 10 Å/second, and under pressures in the range of 10⁻¹⁰ torr to 10 torr). As such, by being in a non-preferential orientation, the organic molecules may exist in an energetically unfavorable orientation based on the balance between the intermolecular forces and the molecule-substrate forces. In some cases, at least 75% of the organic molecules in the templated organic film have a non-preferential orientation with respect to the host substrate.

In an embodiment where one or more structural templating films are pre-deposited on the host substrate and the organic film to be templated is deposited on the one or more structural templating films, the templated organic film would have non-preferential orientation with respect to the underlying host substrate. Because the non-preferential orientation (with respect to the host substrate) of the organic film is the desired long-range crystalline order for the organic film, the one or more structural templating films enable forming the organic film over the host substrate.

For example, in a diindenoperylene (DIP) film grown on a gold substrate under mild deposition conditions, DIP molecules having an upright orientation would be considered to be in a non-preferential orientation. See Durr et al., “Interplay between morphology, structure, and electronic properties at diindenoperylene-gold interfaces,” PHYS. REV. B 68:115428 (2003). In another example, in a DIP film grown on a SiO₂ substrate, DIP molecules having a lying orientation would be considered to be in a non-preferential orientation. See Durr et al., “Observation of competing modes in the growth of diindenoperylene on SiO₂,” THIN SOLID FILMS 503:127-132 (2006). As used herein, “upright orientation” means an orientation in which the long axis of the molecule is aligned at an angle of greater than 45° relative to the substrate surface; and “lying orientation” means an orientation in which the long axis of the molecule is aligned at an angle of 45° or less relative to the substrate surface. In organic electronic devices, such orientation in the various layers of the devices improves the performance of the devices by increasing the charge transport in the direction between the two electrodes.

In general, π-conjugated polycyclic aromatic organic molecules deposited on a metal substrate have been observed to arrange themselves in an orientation that is governed by the molecule-substrate interactions because the adhesion energy is typically significantly stronger than the cohesion energy between the organic molecules. As such, π-conjugated polycyclic aromatic organic molecules deposited on a metal substrate will typically have a lying orientation relative to the metal substrate. Thus, the present disclosure may provide an organic film on a metal host substrate in which the π-conjugated polycyclic aromatic organic molecules in the film are in a non-preferential upright orientation relative to the metal host substrate.

### Examples

Specific representative embodiments of the invention will now be described, including how such embodiments may be made. It is understood that the specific methods, materials, conditions, process parameters, apparatus and the like do not necessarily limit the scope of the invention.

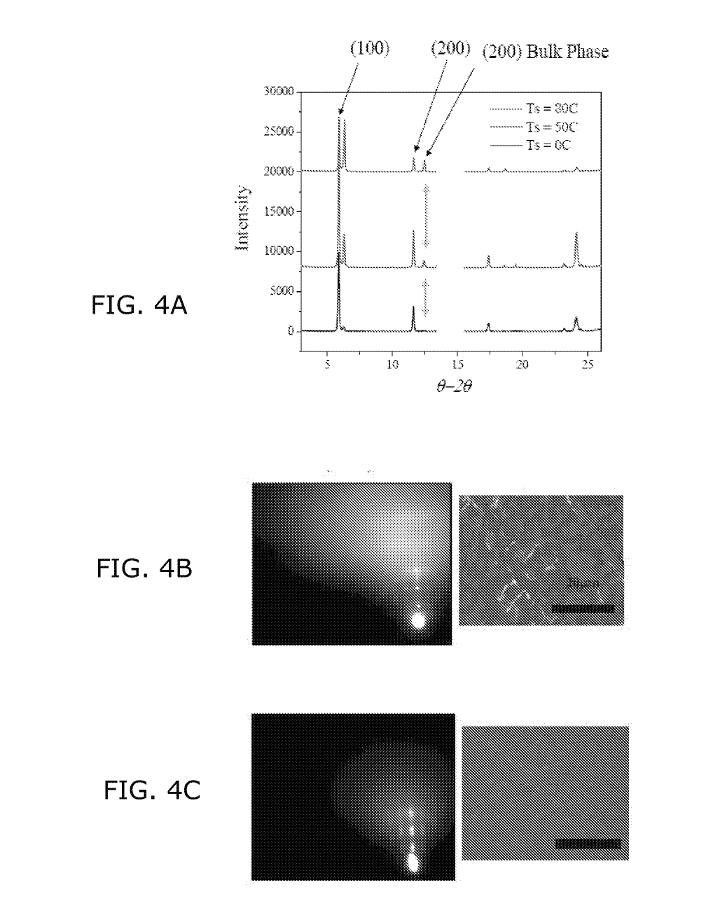

For FIGS. 4A-4C, a 1500 Å thick pentacene film was grown on a [100] KBr substrate at various substrate temperatures (T_{sub}=80, 50, and 0° C.). FIG. 4A shows the x-ray diffraction spectra obtained for the three pentacene films. The upper plot is for the pentacene film grown at T_{sub}=80° C., the middle plot is for the pentacene film grown at T_{sub}=50° C., and the lower plot is for the pentacene film grown at T_{sub}=0° C.

The x-ray diffraction spectra show that the films have varying biphasic content with a single [100] orientation. The two phases are referred to as a thin-film phase (with a larger lattice spacing) and the bulk-phase (with a smaller lattice constant). This series of spectra also demonstrates that the peaks associated with the bulk phase diminish with lower substrate temperatures when grown on KBr. At T_{sub}=0° C., the film becomes nearly monophasic.

FIG. 4B shows a reflection high-energy electron diffraction (RHEED) pattern obtained for the pentacene film grown at T_{sub}=80° C., and the corresponding cross-polarized optical microscopic image of the film surface showing the biphasic (−50%) nature of the film. FIG. 4C shows a RHEED pattern obtained for the pentacene film grown at T_{sub}=0° C., and the corresponding cross-polarized optical microscopic image of the film surface. Again, these images demonstrate that the film becomes progressively more monophasic with decreasing substrate temperatures.

Pentacene is also known to grow in an upright orientation on inert surfaces such as silicon oxide (see Ruiz et al., “Pentacene ultrathin film formation on reduced and oxidized Si surfaces,” PHYS. REV. B 67:125406 (2003)), while a metal surface (such as silver) promotes a configuration with the long molecular axis parallel to the surface (see Casalis et al., “Hyperthermal Molecular Beam Deposition of Highly Ordered Organic Thin Films,” PHYS. REV. LETT. 90:206101 (2003)).

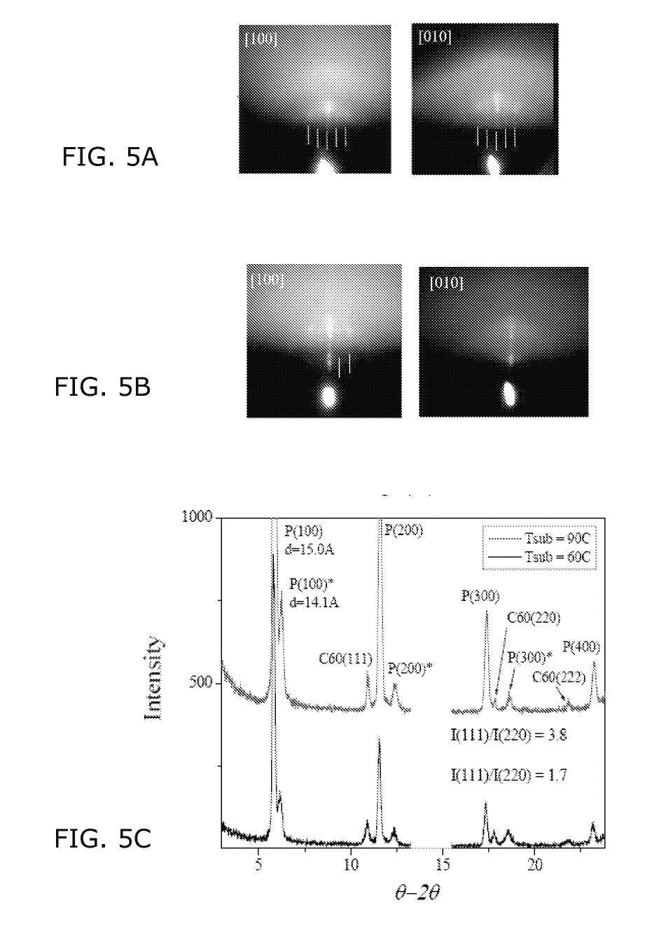

For FIGS. 5A-5C, a 300 Å thick C₆₀ film was grown directly on a pentacene film as described above (grown at T_{sub}=0° C.). The C₆₀ film was deposited at a source flow rate of 25 sccm, deposition rate of 0.2 Å/second, and substrate temperatures of either T_{sub}=60 or 90° C. FIG. 5A shows the RHEED pattern obtained for the C₆₀ film grown at T_{sub}=60° C. The RHEED pattern was obtained by a 20 keV incident beam directed parallel to the (100) and (010) planes of the KBr substrate. FIG. 5B shows the RHEED pattern obtained for the C₆₀ film grown at T_{sub}=90° C. Again, the RHEED pattern was obtained by a 20 keV incident beam directed parallel to the (100) and (010) planes of the KBr substrate. Both FIGS. 5A and 5B show the crystalline quality of the C₆₀ film. These results demonstrate that another organic film (not necessarily an organic film of the method of the present disclosure) can serve as a template substrate for growing an organic film having a well-ordered crystalline structure. Also, it has recently been demonstrated that highly ordered films of 3,4,9,10-perylenetetracarboxylic dianhydride (PTCDA) can be a suitable template substrate for the subsequent growth of structurally ordered copper phthalocyanine films. See Lunt et al., ADV. MATERIALS 19:4229-4233 (2007). PTCDA is notable for its tendency to lie flat when deposited on amorphous substrates such as SiO₂ or rough surfaces such as indium tin oxide (ITO).

FIG. 5C shows the x-ray diffraction spectra for the two C₆₀ films above (T_{sub}=60° C. and 90° C.). The upper plot is for the C₆₀ film deposited at T_{sub}=90° C. and the lower plot is for the C₆₀ film deposited at T_{sub}=60° C. FIG. 5C also shows the various crystalline orientations to which the peaks in the spectra are assigned. Based on the relative intensity of the [111] and [220] peaks, the volume ratio of the [111] phase to the [220] phase in the films were estimated to be 3.8 for the C₆₀ film deposited at T_{sub}=90° C. and 1.7 for the C₆₀ film deposited at T_{sub}=60° C. These results indicate that higher substrate temperatures may promote growth of the [111] phase, which may be desirable in some C₆₀ films.

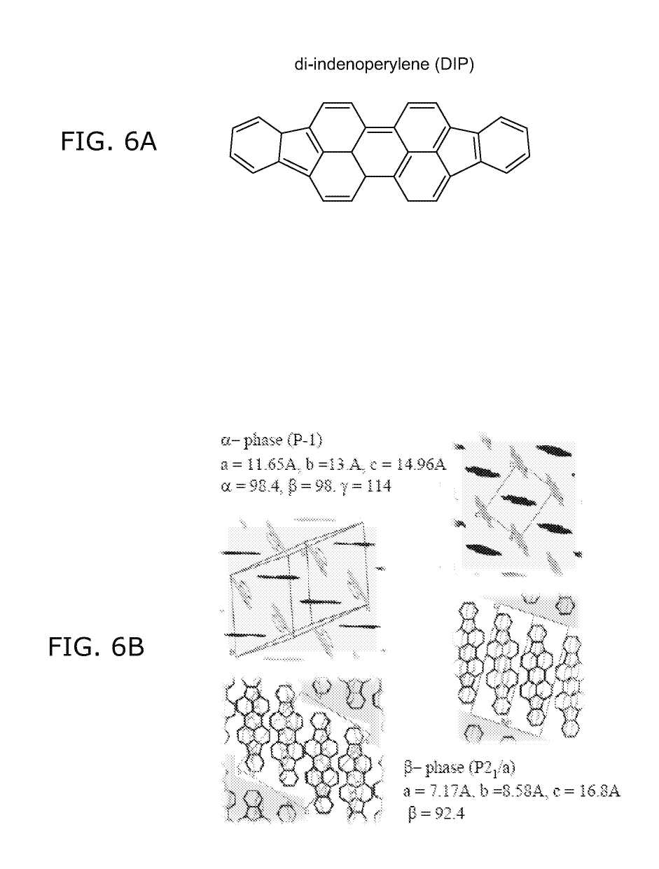

FIG. 6A shows the molecular structure of diindenoperylene (DIP). Two of the known growth modes for a DIP film are the α-phase (also known as λ-phase) and the β-phase (also known as α-phase). In the α-phase, the long axis of the DIP molecules are oriented parallel to the substrate surface. This phase is believed to occur when the DIP molecules have a relatively strong interaction with the substrate. In the β-phase, the long axis of the DIP molecules are in an upright or standing orientation relative to the substrate surface. See Durr et al., “Observation of competing modes in the growth of diindenoperylene on SiO₂,” THIN SOLID FILMS 503:127-132 (2006). This phase is believed to occur when the DIP molecules have a relatively weak interaction with the substrate such that the orientation of the DIP molecules are primarily governed by intermolecular interactions. FIG. 6B shows possible unit cell arrangements of DIP molecules in the α-phase and β-phase. The unit cells are characterized by three lattice parameters: a, b, and c; and angles: α, β, and λ (in degrees).

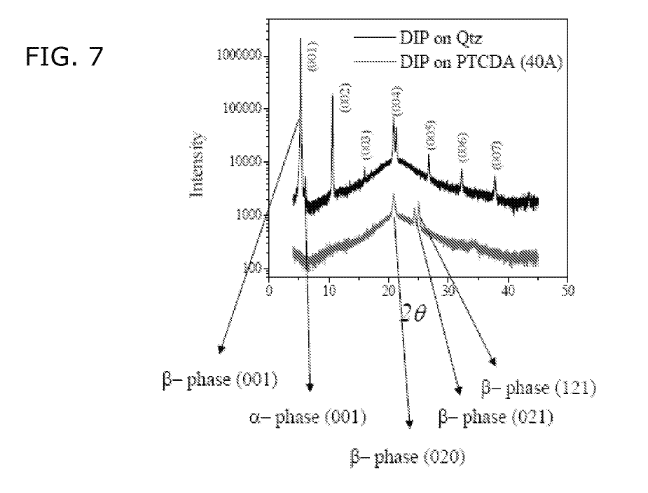

FIG. 7 shows the x-ray diffraction spectra for DIP films grown on quartz and PTCDA (3,4,9,10-perylenetetracarboxylic dianhydride). The upper plot is for the DIP film on SiO₂ and the lower plot is for the DIP film on PTCDA. The x-ray diffraction spectrum of the DIP film on SiO₂ shows the coexistence of both the β-phase and the α-phase, with preferred growth of the β-phase as indicated by the presence of multiple peaks that are associated with the β-phase (upright orientation). For the DIP film on PTCDA, the diffraction peaks are associated with the (020), (021), and (121) planes of the β-phase orientation of the DIP molecules.

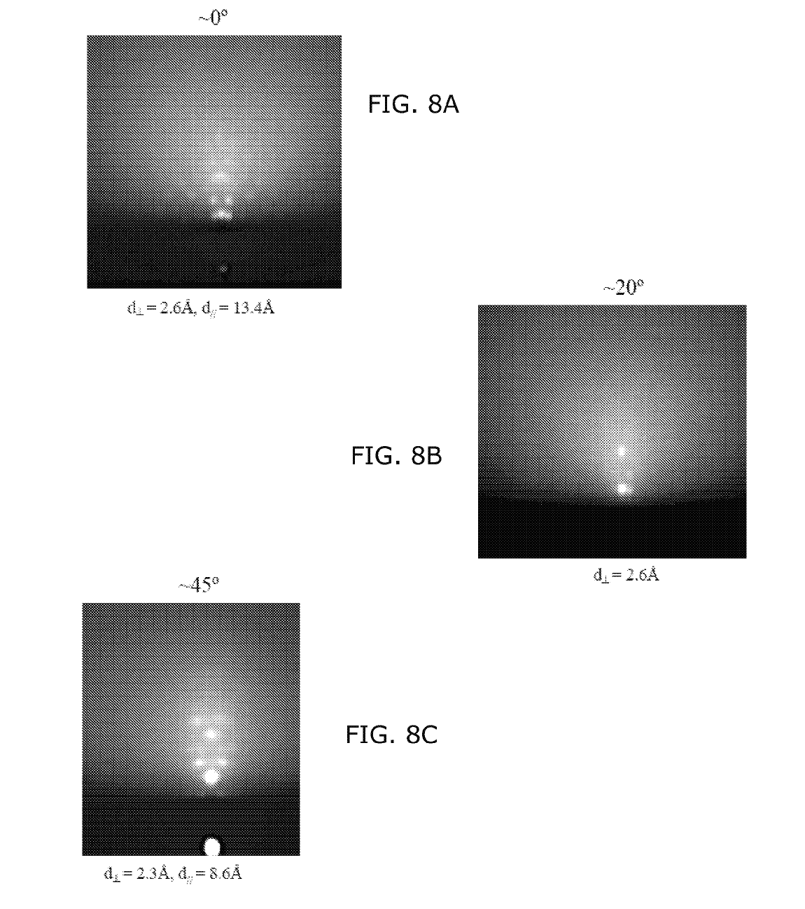

For FIGS. 8A-8C, a DIP film was grown on (001) KBr at 0.2 Å/s, at a pressure of 10 mtorr, and substrate temperature of 20° C. FIGS. 8A-8C show the RHEED patterns obtained at different azimuthal angles. The d-spacings calculated from these RHEED patterns indicate that the long axis of the DIP molecules are lying parallel to substrate α-phase). This indicates that DIP has a strong substrate interaction with KBr. It is also known that a DIP film grows in α-phase on a gold substrate. See Durr et al., “Interplay between morphology, structure, and electronic properties at diindenoperylene-gold interfaces,” PHYS. REV. B 68:115428 (2003).

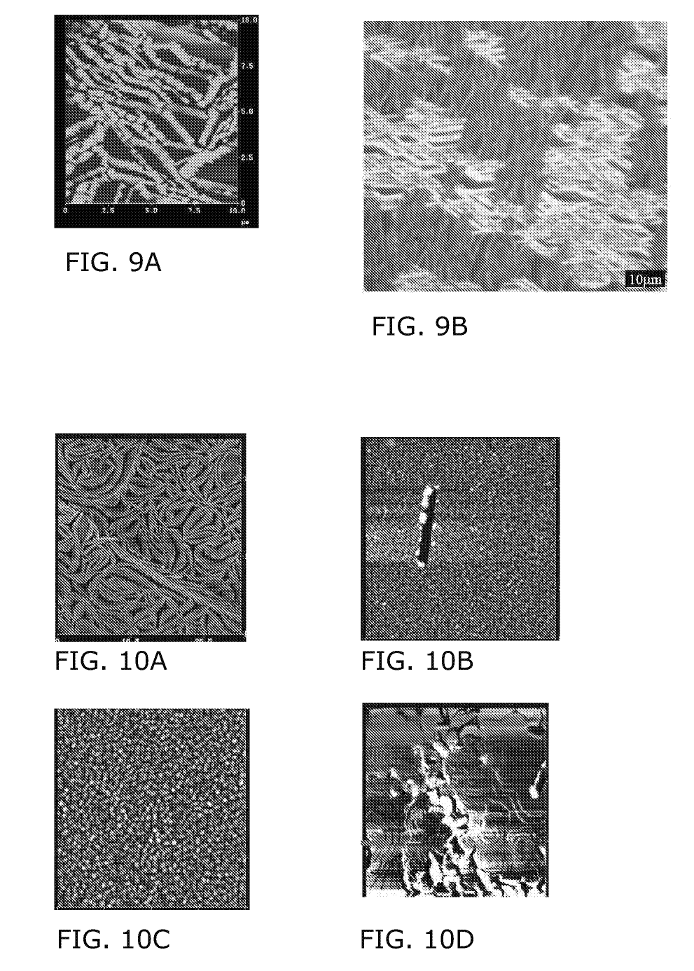

To investigate the surface morphology of the DIP film grown on KBr, the films were imaged by atomic force microscopy and cross-polarized optical microscopy. FIG. 9A is the AFM image of the film and shows the DIP molecules forming elongated fiber-type structures (nanowires) of approximately 500 nm width and 150 nm height. FIG. 9B is the cross-polarized optical microscopic image of the film and confirms the nanowire structure at the surface.

FIGS. 10A-D show atomic force microscopy images of the surface of DIP films grown on various substrates. FIG. 10A shows the surface of a 1,000 Å thick DIP film grown on KBr. FIG. 10B shows the surface of a 1,000 Å thick DIP film grown on silicon. FIG. 10C shows the surface of a 1,000 Å thick DIP film grown on sapphire. FIG. 10D shows the surface of a 500 Å thick DIP film grown on sapphire (note the terrace morphology, which reflects the presence of upright DIP molecules).

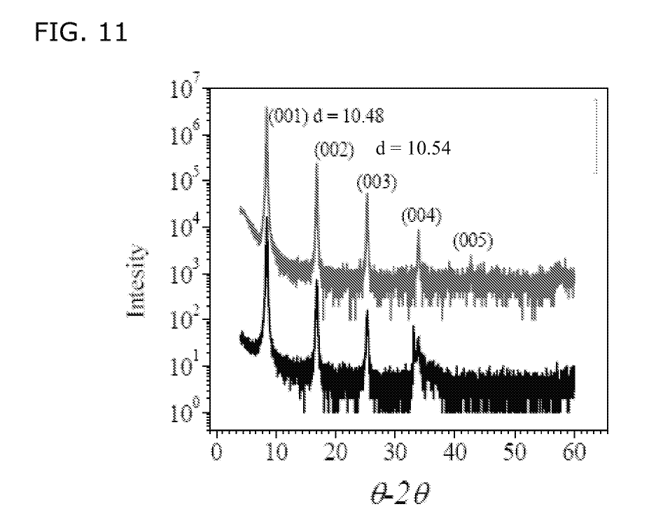

FIG. 11 shows an x-ray diffraction spectra for films formed by organic vapor phase deposition of Pt(pq)(acac): platinum (2-[2′pyridyl]quinoxaline)(acetylacetonate). The upper plot is for the Pt(pq)(acac) film grown on silica quartz and the lower plot is for the Pt(pq)(acac) film grown on sapphire (Al₂O₃). Four major peaks are shown that are associated with the (001) plane oriented parallel to the substrate normal. A smaller peak is possibly associated with a secondary crystalline phase.

In one embodiment, any of the above-described organic films first grown on a template substrate can be transferred to a host substrate in making an organic electronic device. Organic electronic devices of the present disclosure include, but are not limited to, organic light emitting devices (OLEDs), organic field-effect transistors (OFETs), organic thin-film transistors (OTFTs), and organic photosensitive devices (such as organic photovoltaic devices (OPVs or solar cells) and organic photodetectors).

In another embodiment, the organic films having a desired long-range crystalline order (i.e. the upright orientation) can be grown on a host substrate structure (e.g. an electrode layer) of an organic electronic device when the desired long-range crystalline order is a non-preferential arrangement with respect to the host substrate. This can be achieved by first depositing one or more layers of structural templating material on the host substrate and then growing the intended organic film on the structural templating layer(s).

For an organic light emitting device, the organic film having a desired long-range crystalline order may serve as any of the various types of functional organic films used in organic light emitting devices, such as a hole injection layer, a hole transport layer, an electron blocking layer, an emissive layer, a hole blocking layer, an electron transport layer, or an electron injection layer (see, for example, U.S. Appln. Publication No. 2008/0220265 to Xia et al., which is incorporated by reference herein).

In another example, the organic film having a desired long-range crystalline order may serve as any of the various types of functional organic films used in OPVs, such as the donor, acceptor, exciton blocking layer, etc.

We demonstrate that OPV performance is influenced by changes in crystalline orientation of one or more of the photoactive layers controlled via growth of the active layer(s) on ordered crystalline “structural templating” layers. DIP organic film can be used as a secondary structural template and exciton blocking layer when grown on a primary structural template, an ordered layer of 3,4,9,10-perylenetetracarboxylic dianhydride (PTCDA), followed by growth of the copper phthalocyanine (CuPc) donor layer and C₆₀, acceptor layer. Control over the crystalline orientation of CuPc leads to changes in its frontier energy levels, absorption coefficient, morphology, and exciton diffusion length, resulting in an increase of power conversion efficiency under 1 sun, AM1.5G illumination from 1.42±0.04% for an untemplated structure, to 2.19±0.05% when incorporating the multilayer structural template. Our results suggest that crystalline orientation strongly influences organic electronic device characteristics and performance.

One limitation of organic photovoltaics (OPVs) is their low open-circuit voltage (V_{oc}), which is typically three to four times lower than the optical energy gap of the materials employed. Low short-circuit current (J_{sc}) is also typically observed due to the tradeoff between the relatively long optical absorption length and the short exciton diffusion length. According to the present disclosure, an increase in both J_{sc} and V_{oc} can be achieved by controlling the molecular crystalline orientation of the donor layer (e.g. CuPc) by growing the donor layer on a pre-deposited organic structural template layers. This leads to an increase in the PV cell power conversion efficiency, ηₚ. Furthermore, because crystalline structures are morphologically more stable than amorphous structures, the resulting OPV devices will have the potential for greater long term operational reliability.

Although it has been shown that OPVs using a thin 3,4,9,10-perylenetetracarboxlic dianhydride (PTCDA) templating layer exhibit increases in J_{sc}, attributed to the anisotropic charge mobility in the donor CuPc films. However, in those devices, the gains in J_{sc} were offset by decreases in V_{oc} and fill factor (FF) such that the improvement in power efficiency was <10%.

According to the method disclosed herein, however, a combination of a PTCDA film along with a DIP film layers are used for structural templating of the subsequent growth of organic solar cell active layers such as polycrystalline copper phthalocyanine (CuPc) donor layer. While CuPc can be grown on glass with an upright (100)-α-phase molecular configuration, the presence of PTCDA orients the CuPc molecules into a nearly flat-lying configuration that leads to improved π-orbital overlap between molecules, and hence enhanced exciton diffusion and charge transport properties of the donor layer. The nearly flat-lying orientation of CuPc molecules when the film is grown on predeposited structructural templating layers leads to favorable molecular energy level alignments, increased optical absorption coefficients and exciton diffusion lengths, thereby resulting in an increase in the OPV efficiency >50% compared to those using untemplated films.

### Examples

In order to verify the performance benefits on OPV devices, experimental OPV cells were fabricated in laboratory. The organic layers were grown using vapor thermal evaporation technique on 150 nm thick layers of indium tin oxide (ITO) precoated onto glass substrates. Prior to thin film depositions, the substrates were cleaned in tergitol and solvents following previous methods, and then exposed to UV-ozone for 10 min before loading into a high vacuum chamber (base pressure <10⁻⁶ Torr). Purified (by thermal gradient sublimation in vacuum) PTCDA, DIP, CuPc, C₆₀, and bathocuproine (BCP) were thermally evaporated at 0.2, 0.05, 0.1, 0.15, and 0.1 nm/s, respectively, followed by a 100 nm thick Al cathode deposited through a shadow mask with an array of 1 mm diameter openings. For each experiment, CuPc, C₆₀, BCP, and/or Al were grown simultaneously with and without structural templating layers for control purposes.

Current density versus voltage (J-V) characteristics were measured in the dark, under simulated AM1.5G solar illumination, and under various illumination intensities and quantum efficiency measurements were referenced using a NREL-calibrated Si detector. Errors correspond to the standard deviation in values determined by measuring multiple devices on the same substrate. Ultraviolet photoelectron spectroscopy (UPS) measurements were performed on the organic films transferred in nitrogen from the growth chamber to an ultrahigh vacuum system (base pressure <5×10⁻⁹ Torr) where they were illuminated with the He I source. X-ray diffraction (XRD) was performed on a rotating anode Rigaku Cu-Kα diffractometer in the Bragg-Brentano configuration, and atomic force microscope (AFM) images were obtained using a Digital Instruments Nanoscope III in the tapping mode. Photovoltaic active region absorption was estimated from the measurement of device reflectivity (R) at 6° (near-normal) incident angle with an ITO/Al reference sample so that the active layer absorption is equal to (1−R). Internal quantum efficiency (IQE) was calculated as the ratio of the external quantum efficiency (EQE) and the fraction of photons absorbed in the active region.

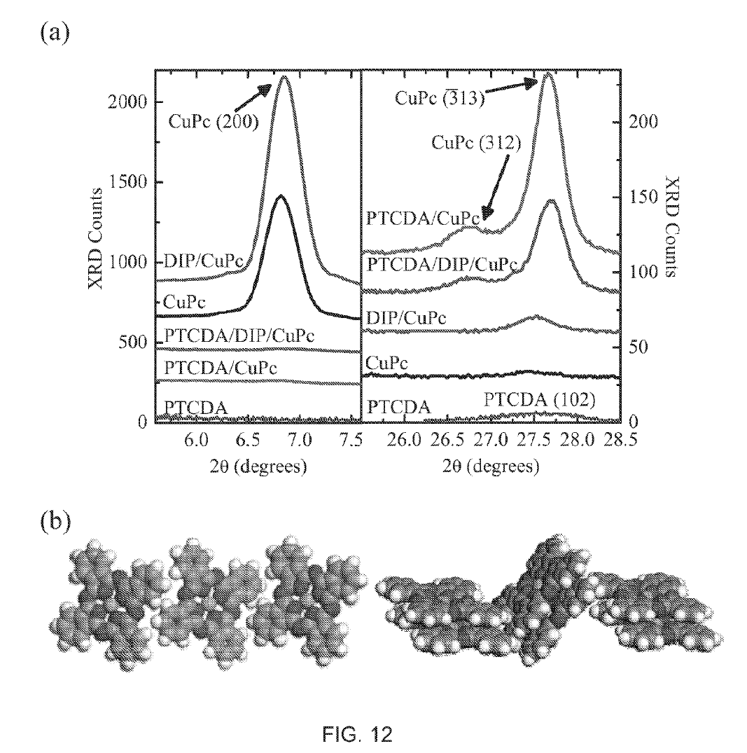

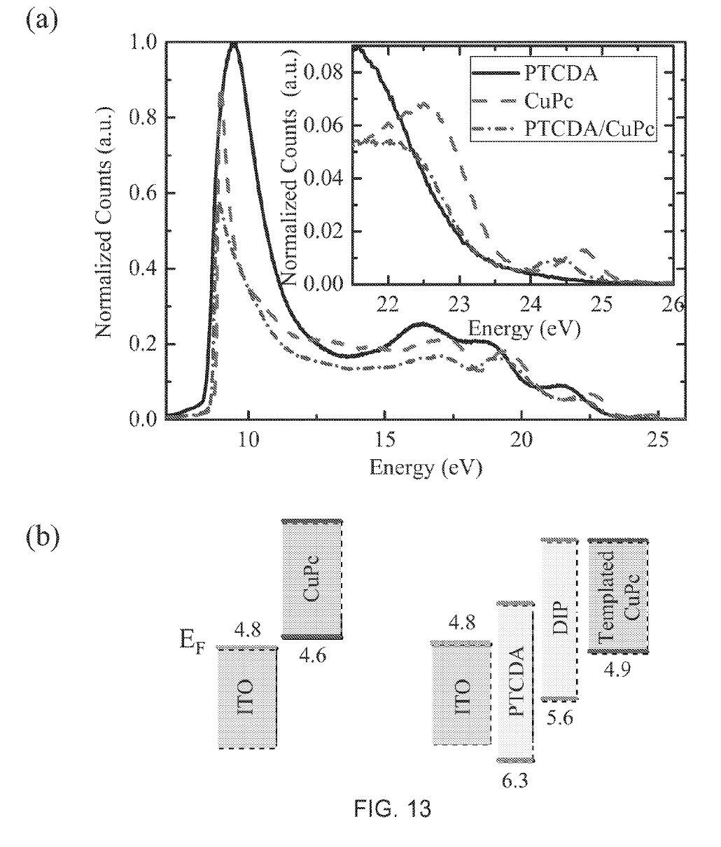

FIG. 12 shows the XRD plots for films grown on oxidized Si substrates. A weak diffraction peak at 20=27.5° is observed for a 1.5 nm thick layer of PTCDA, indicating the existence of the flat-lying α-phase (102) orientation. For a 25 nm thick layer of CuPc, the “standing-up” (long molecular axis perpendicular to the substrate) of the α-phase (200) orientation is inferred from the peak at 20=6.8°. When a 25 nm thick layer of CuPc is grown on a 1.5 nm thick DIP layer, flat-lying α-phase (102) orientation of CuPc is unchanged, whereas, when a 25 nm thick CuPc is grown (i.e. templated) on a 1.5 nm thick layer of PTCDA, the standard standing-up (200) orientation of CuPc disappears while peaks at 20=26.7° and 27.7°, corresponding to the CuPc (312) and ( 3̅13) orientations, appear. When a 25 nm thick CuPc layer is grown on a bilayer of 1.5 nm thick DIP on 1.5 nm PTCDA, similar changes in CuPc orientation to that grown directly on PTCDA is observed. These data shows an unexpected finding that by using PTCDA as a templating layer, we are able to change the orientation of DIP from (001) β-phase on glass to (020) α-phase on PTCDA, which in turn also controls the crystal orientation of CuPc that is deposited on the DIP film. This result was unexpected because depositing CuPc on DIP alone did not change the crystalline orientation of the CuPc layer.

FIG. 13(a) shows ultraviolet photoelectron spectroscopy (UPS) data for PTCDA (1.5 nm thick), CuPc (5.0 nm thick), and PTCDA (1.5 nm thick)/CuPc (5.0 nm thick) on ITO. The dotted lines indicate the high-energy cutoff. The highest occupied molecular orbital (HOMO) energy of CuPc (5 nm thick on ITO) is increased by 0.2-0.3 eV when a 1.5 nm thick layer of PTCDA is used for templating the CuPc, as determined by UPS (observed as a shift in the high energy cutoff from 25.0 eV to 25.2 eV. FIG. 13(b) shows the relative positions of the HOMO levels for PTCDA, DIP, and CuPc inferred from UPS measurements.

FIG. 13(b) shows the energy diagram for the PTCDA 80, DIP 82, and CuPc 90 films formed as described above. As can be seen by the energy diagram, the CuPc 90 and PTCDA 80 films create a Type-II heterojunction that would generate photocurrent in opposition to the PV device's operation. However, by incorporating the thin DIP layer as exciton blocking layer, losses at the PTCDA/CuPc interface can be minimized. Furthermore, the absorption coefficient of CuPc increases by approximately 30% with templating into the (312) orientation (data not shown). Although DIP is photoactive, because DIP layer is provided only in the very thin form factor (1.5 nm), any excitons generated by the DIP layer is negligible.

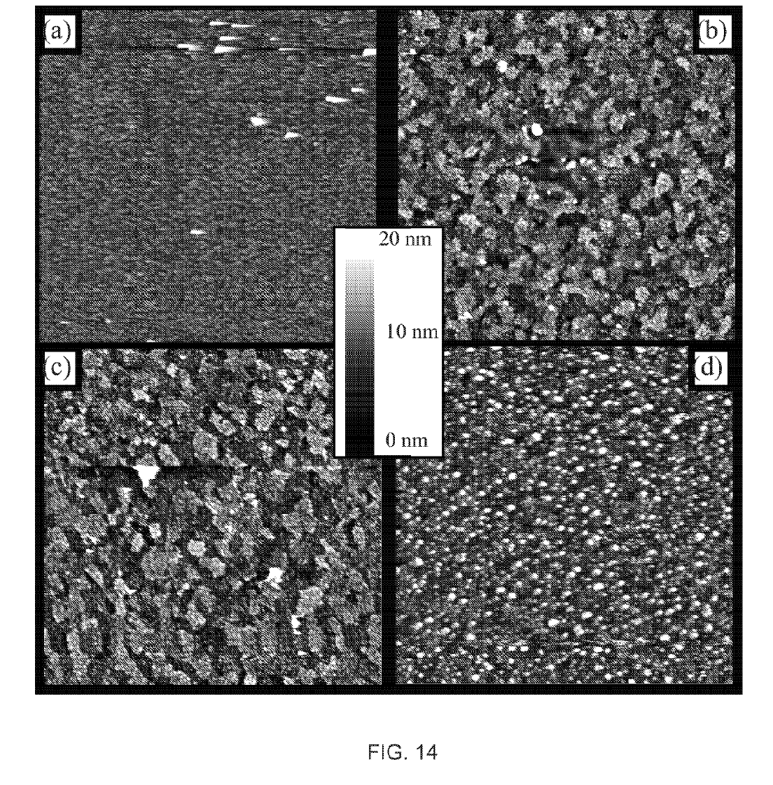

Another observation was that the morphology of the CuPc films changes from a smooth film with a root mean square (RMS) roughness of 1.8 nm when grown directly on ITO (FIG. 14(a)), to a roughness of 3.9 nm when grown on either a PTCDA or DIP singular templates (see FIGS. 14(b) and 14(c)) where the underlying grain structure of ITO becomes apparent. Using the multilayer templating that combines a DIP film on top of a PTCDA film, a CuPc morphology with a roughness of 6.8 nm and an island size of ˜100 nm was obtained, as shown in FIG. 14(d).

The OPV device performance under one sun illumination is summarized in Table 1 for the following device structures: glass/ITO/templating layer(s)/(25 nm) CuPc/(40 nm) C₆₀/(10 nm) BCP/Al. The Device (I) was a control and did not have any templating layer. Device (II) had 1.5 nm of DIP layer as the templating layer. Device (III) had 1.5 nm of PTCDA layer as the templating layer. Device (IV) had 1.5 nm of DIP on 1.5 nm of PTCDA as the templating layers. The efficiency of the control device (I) was 1.42±0.04%. Device (II) performed similar to the untemplated control device, while for Device (III), structural templating lead to an increase of 0.06 V in V_{oc} and a small increase in J_{sc}, resulting in ηₚ=1.76±0.04%. This increase in V_{oc} is attributed to the increase in the HOMO energy of CuPc as shown in FIG. 13(b). This is consistent with the understanding in the art suggesting that V_{oc} is proportional to the interface energy gap (defined as the difference between the donor HOMO and acceptor lowest unoccupied molecular orbital, or LUMO). Templating with both PTCDA and DIP in Device (IV) shows the same V_{oc} as for Device (III), while J_{sc} is substantially increased, leading to ηₚ=2.19±0.05%. The FF for all devices is ≧0.60, showing that all have similar diode characteristics and shunt resistances under illumination.

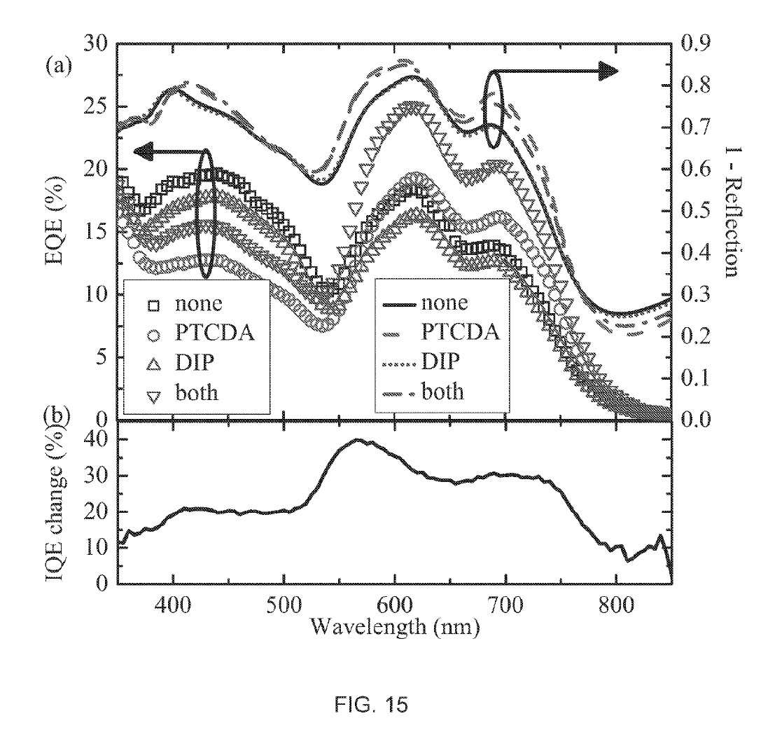

The mechanisms for efficiency enhancement are further understood in terms of the internal and external quantum efficiencies. FIG. 15(a) shows EQE (plotted with symbols) and absorption (lines) for the devices in Table 1. For Devices (II) and (IV) employing a PTCDA template, the absorption is increased between wavelengths of λ=550 nm and 750 nm due to the increase in CuPc absorption, leading to an increase in EQE in the same region, accompanied by a decrease in EQE at shorter wavelengths. Comparing Device (III) to Device (IV), the IQE increases by between 15% and 40% across the entire spectrum, as seen in FIG. 15(b). This is due to a combination of increased interface area between the CuPc and C₆₀ layers (c.f. FIG. 3), decreased exciton quenching at the PTCDA/CuPc interface, and an increase of exciton diffusion length in CuPc due to the change in orientation, all of which lead to increased photocurrent generation.

TABLE 1
OPV performance for the structure glass/ITO/templating
layer(s)/25 nm thick CuPc/40 nm thick C₆₀/10 nm
thick BCP/Al under simulated 1 sun, AM1.5G illumination.

| | Templating | | | | |
|---|---|---|---|---|---|
| | Layer | V_{oc} (V) | FF | J_{sc} (mA/cm²) | ηₚ (%) |
| Device (I) | None | 0.48 | 0.60 | 4.9 | 1.42 ± 0.04 |
| Device (II) | DIP | 0.47 | 0.60 | 5.0 | 1.42 ± 0.19 |
| Device (III) | PTCDA | 0.54 | 0.61 | 5.4 | 1.76 ± 0.04 |
| Device (IV) | Both | 0.54 | 0.62 | 6.6 | 2.19 ± 0.05 |

The above-presented data demonstrate improved OPV performance as a result of changes in crystalline orientation of the donor layer achieved by multilayer structural templating of the organic donor layer. Using the combination of PTCDA and DIP as templating layers, the CuPc stacking was modified from a standing-up (200) β-phase to a flat-lying (312) α-phase orientation. This leads to improvement in orbital overlap between adjacent molecules, and hence favorable changes in frontier energy levels, absorption coefficient, morphology, and exciton diffusion length. DIP serves as a both a structural templating and exciton blocking layer between the PTCDA and CuPc. The OPV efficiency thereby increases from 1.42±0.04% to 2.19±0.05% by the improved stacking arrangements of CuPc in a CuPc/C₆₀ OPV cell. Our results show the impact of controlling the crystalline morphology and orientation on organic optoelectronic properties, which can be utilized to increase OPV efficiency.

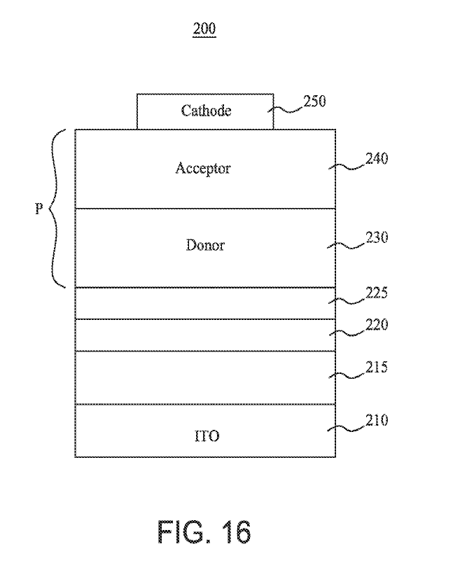

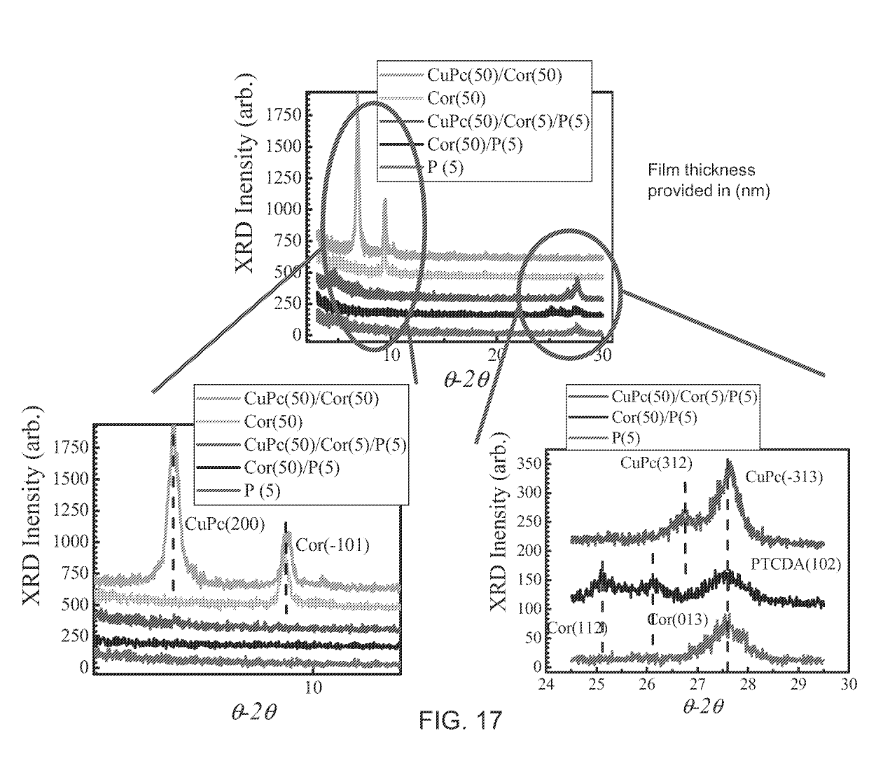

Thus, as shown in FIG. 16, an example of an OPV device 200 incorporating the structural templating method described herein can comprise the following: a first electrode layer (such as ITO) 210; at least one structural templating layer 220 deposited over the first electrode (anode or cathode) layer 210; a photoactive region P disposed on the at least one structural templating layer 220; and a second electrode (cathode or anode) layer 250 disposed over the photoactive region P. The photoactive region P can comprise an organic donor material 230 and an organic acceptor material 240 that are deposited as films and form donor-acceptor heterojunction. Whether the electrode layers 210, 250 are cathode or anode depends upon the direction of the charge carrier flow determined by the orientation of the donor-acceptor heterojunction.

In one embodiment, the donor material 230 is deposited first directly on the structural templating layer 220 and the acceptor material 240 is deposited on the donor material, thus allowing the donor material 230 to be templated to have a desired ordered molecular arrangement. In another embodiment, the acceptor material 240 is deposited first on the structural templating layer 220 (inverted order from FIG. 16) thus allowing the acceptor material 240 to be templated to have a desired ordered molecular arrangement.

In the embodiment where the donor material 230 is templated, forming the film of organic donor material 230 directly on the structural templating layer 220 allows the organic donor material 230 to have the desired ordered molecular arrangement wherein at least a majority of the donor molecules are in a non-preferential orientation with respect to the first electrode or the anode layer 210. The non-preferential orientation refers to the long-range crystalline order of the donor material 230 that would be different or not possible if the donor material 230 were directly formed on the anode layer 210. According to one embodiment, at least 75% of the donor molecules are in the non-preferential orientation with respect to the first electrode layer. In the embodiment where the acceptor material 240 is templated, this applies to the molecules of the acceptor material.

Some suitable organic semiconductor donor materials include, but are not limited to, metallo-phthalocyanine (e.g. CuPc, ClAlPc, etc.), metal-free phthalocyanine, NPD (4,4′-bis(N-(1-napthyl)phenylamino)biphenyl), pentacene, tetracene, and the like. Some suitable organic semiconductors for the acceptor material 240 include, but are not limited to, C₆₀, [84]PCBM ([6,6]-Phenyl C₈₄ butyric acid methyl ester), F₁₆—CuPc, PTCBI (3,4,9,10 perylenetetracarboxylic bisbenzimidazole), PTCDA (3,4,9,10 perylene-tetracarboxylic dianhydride), or Poly(benzimidazobenzophenanthroline), TCNQ (7,7,8,8-tetracyanoquinodimethane), F4-TCNQ (tetrafluorotetracyanoquinodimethane), and the like.

According to another embodiment, the OPV device 200 comprises at least one structural templating layer 220. The at least one structural templating layer 220 can be a PTCDA film as a primary structural templating layer and a secondary structural templating layer 225 is deposited directly on the PTCDA layer 220, where the secondary structural templating layer 225 also provides the exciton blocking function. The secondary structural templating layer 225 comprises another organic material having a perylene core, other than PTCDA. Non-limiting examples of materials having perylene core are diindenoperylene (DIP) and coronene. The secondary structural templating layer 225 can also be highly-oriented pyrolytic graphite (HOPG).

In addition to the data provided above for using DIP as the secondary structural templating layer deposited on PTCDA primary structural templating layer, the inventors have shown that another organic material having a perylene core, coronene, can be used as the secondary structural templating layer 225. FIG. 17 shows x-ray diffraction spectra for the following films deposited on Si substrate: PTCDA (5 nm thick); coronene (50 nm thick)/PTCDA (5 nm thick); CuPc (50 nm thick)/coronene (5 nm thick)/PTCDA (5 nm thick); coronene (50 nm thick); CuPc (50 nm thick)/coronene (50 nm thick). The coronene film on Si exhibit ( 1̅01) orientation peak and the CuPc/Coronene on Si exhibit (200) and ( 1̅01) peaks all representing the upright orientation of the organic molecules. In comparison, the CuPc/coronene/PTCDA film exhibit (312) and ( 3̅13) peaks showing the templating effect of the coronene/PTCDA structural templating layers. The (312) and ( 3̅13) peaks represent the flat or lying orientation that are non-preferential orientation with respect to the Si substrate.

In the embodiment where the acceptor material 240 is templated, the at least one structural templating layer 220 can comprise one or more layers of linear acenes (e.g. pentacene), PTCDA, or crystalline NPD.

According to another embodiment, the structural templating layers (PTCDA alone or PTCDA/DIP combination) can be used to structurally template and obtain a desired molecular arrangement in other functional layers of the OPV device. For example, the structural templating layers can be used to template an exciton blocking layer (other than the DIP layer itself), if one is present in the OPV device structure.

An optional anode-smoothing layer 215 may be provided between the first electrode (anode) layer 210 and the donor layer 230. Anode-smoothing layers are described in U.S. Pat. No. 6,657,378 to Forrest et al., the contents of which are incorporated herein by reference for its disclosure related to this feature.

The method for making the OPV device 200 comprises providing a first electrode layer 210, forming at least one structural templating layer 220 over the first electrode layer 210, forming a photoactive region P disposed on the at least one structural templating layer 220, and providing a second electrode layer disposed over the photoactive region P, wherein the donor material or the acceptor material of the photoactive region P is templated by the at least one structural templating layer and thus have an ordered molecular arrangement.

In the embodiment where the donor material is templated, the step of forming the photoactive region P comprises forming a film of the donor material 230 first directly on the structural templating layer 220 and then forming a film of the acceptor material 240 on the film of the donor material 230. In the embodiment where the acceptor material is templated, the step of forming the photoactive region P comprises forming a film of the acceptor material 230 first directly on the structural templating layer 220 and then forming a film of the donor material 230 on the film of the acceptor material 240 (inverted order from FIG. 16).

In another embodiment, the method for making the OPV device 200 further comprises forming the secondary structural templating layer 225 directly on the primary structural templating layer 220 before forming the photoactive region P. film 230 of an organic donor material.

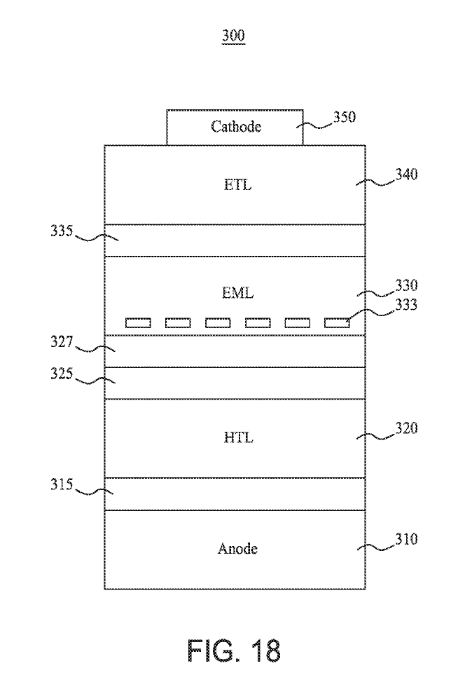

FIG. 18 is a schematic illustration of an OLED 300 according to another embodiment of the present disclosure. The OLED 300 comprises an anode layer 310 and a cathode layer 350. Disposed between the two electrodes are at least one structural templating layer 325 and an organic functional layer disposed over the at least one structural templating layer 325. The organic functional layer can be an optional hole transporting layer 320, an organic emissive layer 330, or an optional electron transporting layer 340. The organic emissive layer 330 may be a neat layer or can comprise a host material that is doped with a dopant material 333. The dopant can be a phosphorescent dopant or a fluorescent dopant. Creating a crystalline order in the organic functional layer is desired to improve luminous efficiency of the OLED 300.

Where the functional layer disposed over the structural templating layer 325 is the organic emissive layer 330, the molecules of the emissive layer 330 obtains the desired molecular arrangement that is in non-preferential orientation with respect to the layer immediately below the structural templating layer 325. Where the optional hole transporting layer 320 is not provided, the anode layer 310 would be immediately below the structural templating layer 325 and the majority of the molecules of the emissive layer 330 are in the non-preferential orientation with respect to the anode layer. Where the organic emissive material for the emissive layer 330 is a doped material, depositing the doped organic emissive layer 330 on the structural templating layer 325 will arrange a majority of both the host molecules and the dopant molecules 333 to have the desired ordered molecular arrangement.

The non-preferential orientation of the ordered molecular arrangement refers to the long-range crystalline order of the molecules of the organic functional layer being structurally templated that would be different or not possible if the organic functional layer molecules were directly formed on the underlying substrate without the structural templating layer 325. According to a preferred embodiment, at least a majority of the templated organic functional layer molecules are in the non-preferential orientation with respect to the layer immediately below the structural templating layer. In some embodiments, at least 75% of the molecules are in the non-preferential orientation. Templating the emissive layer 330 using the embodiments of the method described herein orients the radiative dipole which in turn reduces waveguiding and enhances outcoupling in the OLED 300.

An example of the at least one structural templating layer 325 for controlling the crystalline orientation of the dopant material 333 in the emissive layer is PTCDA whose molecules lie flat when deposited on amorphous substrates such as SiO₂ or rough surfaces such as ITO. In one embodiment, the doped organic emissive layer 330 is deposited directly on the PTCDA layer 325.

In another embodiment, the at least one structural templating layer 325 comprises a PTCDA film as a primary structural templating layer and an additional secondary structural templating layer 327 deposited directly on the structural templating layer 325 before the doped emissive layer 330 is deposited. The secondary structural templating layer 327 is also an exciton blocking layer that helps to confine the excitons to the emissive layer 330 during the operation of the OLED. According to an embodiment, the secondary structural templating layer 327 comprises another organic materials having a perylene core, other than PTCDA. Non-limiting examples of materials having a perylene core are DIP and coronene. The secondary structural templating layer 327 can also be highly-oriented pyrolytic graphite (HOPG).

The dopant material 333 in this embodiment can be a phosphorescent compound from the class of compounds defined by phthalocyanines, porphyrins, and perylene-cored molecules. Pt(II) Octaethylporphine (PtOEP) is one example of the phosphorescent dopant material.

Emissive layer 330 may include an organic material capable of emitting light when a current is passed between anode 310 and cathode 350. The emissive layer 330 can contain a phosphorescent emissive material or a fluorescent emissive material. The emissive layer 330 may also comprise a host material capable of transporting electrons and/or holes, doped with an emissive material that may trap electrons, holes, and/or excitons, such that excitons relax from the emissive material via a photoemissive mechanism. The emissive layer 330 may comprise a single material that combines transport and emissive properties. Whether the emissive material is a dopant or a major constituent, emissive layer 330 may comprise other materials, such as dopants that tune the emission of the emissive material. The emissive layer 330 may include a plurality of emissive materials capable of, in combination, emitting a desired spectrum of light. Examples of phosphorescent emissive materials include phthalocyanines, porphyrins, and perylene-cored molecules. Pt(II) Octaethylporphine (PtOEP) and Ir(ppy)₃ are some examples of phosphorescent emissive materials. Examples of fluorescent emissive materials include DCM and DMQA. Examples of host materials include Alq₃, CBP and mCP. Examples of emissive and host materials are disclosed in U.S. Pat. No. 6,303,238 to Thompson et al., which is incorporated by reference in its entirety.

The hole transport layer 320 may include a material capable of transporting holes. The hole transport layer 320 may be intrinsic (undoped), or doped. Doping may be used to enhance conductivity. α-NPD and TPD are examples of intrinsic hole transport layers. An example of a p-doped hole transport layer is m-MTDATA doped with F₄-TCNQ at a molar ratio of 50:1, as disclosed in United States Patent Application Publication No. 2003-0230980 to Forrest et al., which is incorporated herein by reference in its entirety. Other hole transport layers may be used

The electron transport layer 340 may include a material capable of transporting electrons. The electron transport layer 340 may be intrinsic (undoped), or doped. Doping may be used to enhance conductivity. Alq₃ is an example of an intrinsic electron transport layer. An example of an n-doped electron transport layer is BPhen doped with Li at a molar ratio of 1:1, as disclosed in United States Patent Application Publication No. 2003-0230980 to Forrest et al., which is incorporated by reference in its entirety. Other electron transport layers may be used.

A method for making the OLED 300 comprises providing a first electrode layer 310, providing a second electrode layer 350, forming at least one structural templating layers (315, 325, 335) disposed between the first and second electrodes, and forming an organic functional layer (e.g. 330, 320, or 340) disposed over the at least one structural templating layers, wherein the functional layer has its molecules in an ordered molecular arrangement, wherein at least a majority of the molecules of the functional layer are in a non-preferential orientation with respect to the layer immediately below the at least one structural templating layer. The organic functional layer can be the organic emissive layer 330, the optional organic hole transporting layer 320, or the optional electron transporting layer 340. In some embodiments, the OLED 300 can include more than one of the optional layers in combination with the emissive layer 330. When provided, the organic hole transporting layer 320 is deposited directly on the first electrode layer 310 before depositing the at least one structural templating layer 325. When provided, the organic electron transporting layer 340 is deposited over the organic emissive layer 330 before depositing the second electrode layer 350. In another embodiment, the method for making the OLED 300 further comprises forming a secondary structural templating layer 327 that also functions as an exciton blocking layer deposited directly on the primary structural templating layer 325 before the emissive layer 330 is deposited.

According to another aspect of the present disclosure, the hole transporting layer 320 and the electron transporting layer 340 can be structurally templated to have a desired molecular arrangement. To structurally template these charge carrier transporting layers, at least one structural templating layers can be provided at appropriate positions in the OLED structure. For example, at least one structural templating layer 315 can be deposited on the anode layer 310 for templating the hole transporting layer 320. In another embodiment, at least one structural templating layer 335 is deposited on the emissive layer 330 for templating the electron transporting layer 340.

Therefore, we have described three possible locations for structural templating layers in the stack of organic semiconductor layers of the OLED 300. Depending upon the particular need, structural templating layers can be provided in all three locations 315, 325, 335 to obtain desired molecular arrangement in all three of the hole transporting layer 320, the emissive layer 330, and the electron transporting layer 340. In other embodiments, only the appropriate structural templating layers can be provided to obtain the desired molecular arrangement in only one or two of the three functional layers discussed. Thus, the present disclosure encompasses all possible permutations of the use of the three locations 315, 325, 335 for the structural templating layers.

### Example

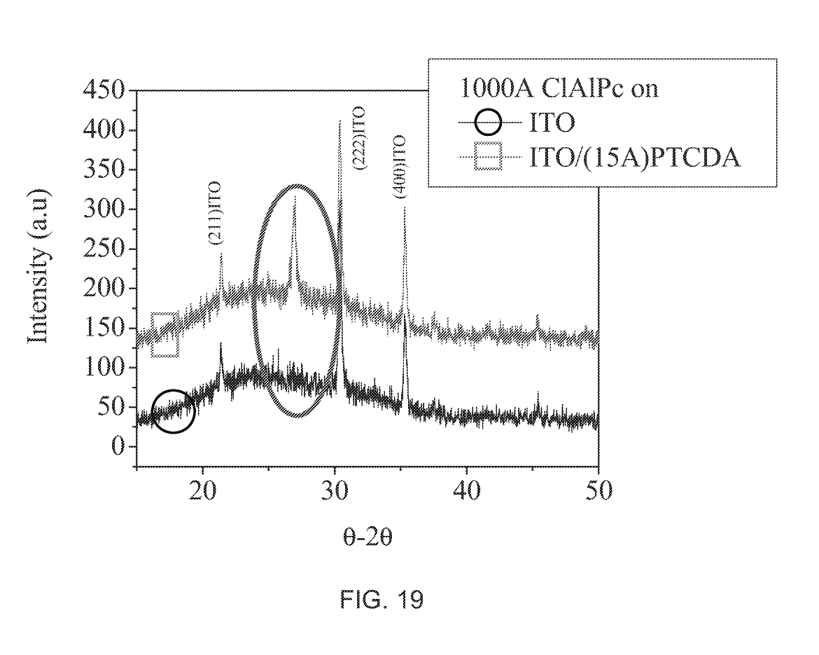

The inventors have shown that hole transporting layers and the electron transporting layers can be structurally templated to obtain a desired molecular arrangement. FIG. 19 shows XRD data for a potential hole transport layer, chloroaluminium phthalocyanine (ClAlPc). For vapor phase growth of 100 nm thick ClAlPc on ITO substrates, an amorphous film of ClAlPc is formed and the XRD plot shows only the crystalline peaks of ITO. The legend in FIG. 19 identifies the XRD plot line associated with ClAlPc deposited on ITO. In contrast, ClAlPc film grown on a crystalline structural templating layer of PTCDA deposited in ITO results in a crystalline film of ClAlPc with the close-packing orientation normal to the substrate. The crystalline peak associated with the ClAlPc's crystalline order is identified by the oval. This change in crystalline order, with specific orientation, is anticipated to increase the hole mobility of such a layer which, in turn, will increase the luminescent efficiency of the OLED.

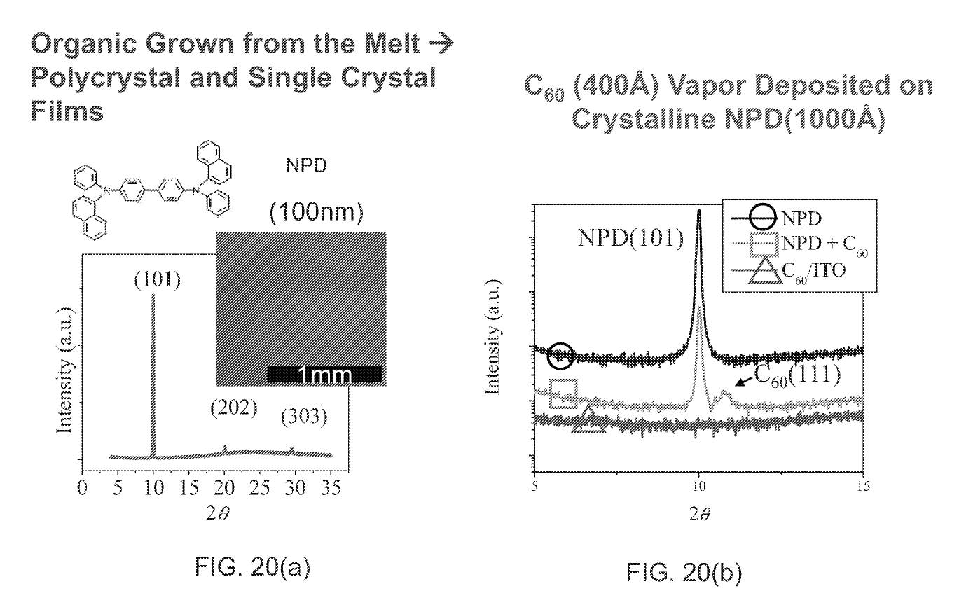

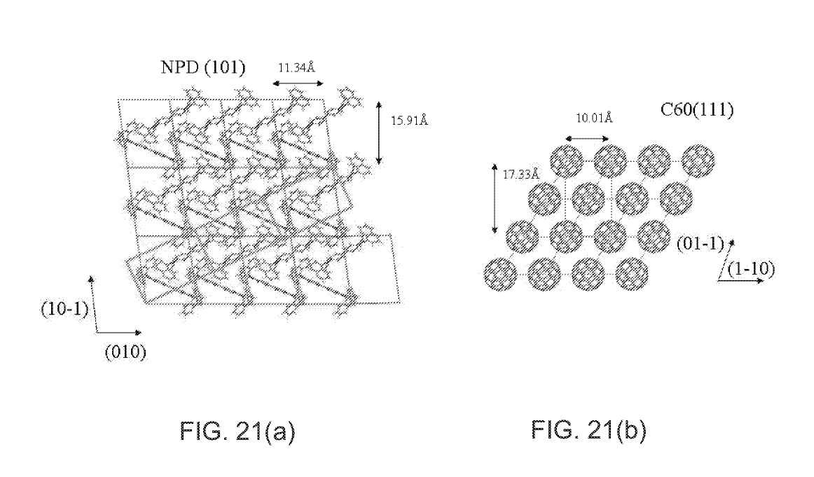

In FIG. 20, we demonstrate the ability to template the crystalline growth of C₆₀, a potential electron transport layer. As shown by the lack of any C₆₀ crystalline peaks in the XRD plot for C₆₀/ITO in FIG. 20(b), when C₆₀ is grown directly on ITO substrate, an amorphous film is formed. When grown on a crystalline templating layer of N,N′-diphenyl-N,N′-bis(1-naphthyl)-1,1′biphenyl-4,4″diamine (NPD) via vapor deposition, the C₆₀ layers form crystalline films oriented with the close packed (111) orientation normal to the substrate as observed with x-ray diffraction. The crystal structure orientations of both the NPD(101) and C₆₀(111) are shown in FIGS. 21(a) and (b), respectively.

In an example OLED architecture according to an embodiment, PTCDA templated ClAlPc can be the hole transporting layer, followed by another PTCDA templating layer if necessary to template the emissive layer (can be doped with phosphorescent or flouresecent dopants), followed by another PTCDA, or NPD layer if necessary to template a C₆₀ electron transporting layer.

The foregoing description and examples have been set forth merely to illustrate the invention and are not intended to be limiting. Each of the disclosed aspects and embodiments of the present disclosure may be considered individually or in combination with other aspects, embodiments, and variations of the invention. In addition, unless otherwise specified, none of the steps of the methods of the present disclosure are confined to any particular order of performance. Modifications of the disclosed embodiments incorporating the spirit and substance of the invention may occur to persons skilled in the art and such modifications are within the scope of the present invention.

What is claimed is:

1. An organic photosensitive device, comprising:
a first electrode layer;
at least one structural templating layer disposed on the first electrode layer;
a photoactive region disposed on the at least one structural templating layer, the photoactive region comprising a film of an organic donor material and a film of an organic acceptor material forming a donor-acceptor heterojunction,
wherein the donor material or the acceptor material is templated by the at least one structural templating layer and thus having an ordered molecular arrangement,
wherein at least a majority of the molecules of the templated donor or acceptor material are in a non-preferential orientation with respect to the first electrode layer; and
a second electrode layer disposed over the photoactive region.

2. The organic photosensitive device of claim 1, wherein the at least one structural templating layer comprising a second structural templating layer that is an exciton blocking layer.

3. The organic photosensitive device of claim 1, wherein the at least one structural templating layer comprising a layer of 3,4,9,10-perylenetetracarboxylic dianhydride (PTCDA) deposited directly on the first electrode layer as a primary structural templating layer and a secondary structural templating layer deposited directly on the PTCDA layer, wherein the secondary structural templating layer is an exciton blocking layer.

4. The organic photosensitive device of claim 3, wherein the donor material is templated by the at least one structural templating layer and the secondary structural templating layer comprises another organic material having a perylene core, other than PTCDA.

5. The organic photosensitive device of claim 4, wherein the another organic material having a perylene core is diindenoperylene.

6. The organic photosensitive device of claim 3, wherein the secondary structural templating layer comprises highly-oriented pyrolytic graphite.

7. The device of claim 1, wherein the first electrode layer surface does not have an ordered crystalline structure.

8. The device of claim 1, wherein the film of the templated organic donor or acceptor material is neither epitaxial nor quasi-epitaxial with the first electrode layer surface.

9. The device of claim 1, wherein the film of the templated organic donor or acceptor material has a film thickness of 300 Å or greater.

10. The device of claim 1, wherein the film of templated organic donor or acceptor material has a film thickness in the range of 300 Å-3000 Å.

11. The device of claim 1, wherein at least 75% of the templated organic donor or organic acceptor molecules are in the non-preferential orientation.

12. The device of claim 1, further comprising an anode smoothing layer provided between the first electrode layer and the at least one structural templating layer.

13. The device of claim 1, wherein the acceptor material is templated by the at least one structural templating layer and the at least one structural templating layer comprises one or more layers of linear acenes, PTCDA, or crystalline NPD.

14. A method for making an organic photosensitive device, comprising:
providing a first electrode layer;
forming at least one structural templating layer on the first electrode layer;
forming a photoactive region disposed on the at least one structural templating layer, the photoactive region comprising an organic donor material and an organic acceptor material forming a donor-acceptor heterojunction,
wherein the donor material or the acceptor material is templated by the at least one structural templating layer and thus having an ordered molecular arrangement,
wherein at least a majority of the molecules of the templated donor or acceptor material are in a non-preferential orientation with respect to the first electrode layer; and
providing a second electrode layer disposed over the photoactive region.

15. The method of claim 14, wherein the at least one structural templating layer comprising a second structural templating layer that is an exciton blocking layer.

16. The method of claim 14, wherein the at least one structural templating layer comprising a layer of 3,4,9,10-perylenetetracarboxylic dianhydride (PTCDA) deposited directly on the first electrode layer as a primary structural templating layer and a secondary structural templating layer deposited directly on the PTCDA layer, wherein the secondary structural templating layer is an exciton blocking layer.

17. The method of claim 16, wherein the donor material is templated by the at least one structural templating layer and the secondary structural templating layer comprises another organic material having a perylene core, other than PTCDA.

18. The method of claim 17, wherein the another organic material having a perylene core is diindenoperylene.

19. The method of claim 16, wherein the secondary structural templating layer comprises highly-oriented pyrolytic graphite.

20. The method of claim 14, wherein the first electrode layer surface does not have an ordered crystalline structure.

21. The method of claim 14, further comprising providing an anode smoothing layer between the first electrode layer and the at least one structural templating layer

22. The method of claim 14, wherein the acceptor material is templated by the at least one structural templating layer and the at least one structural templating layer comprises one or more layers of linear acenes, PTCDA, or crystalline NPD.

23. An organic light emitting device comprising:
a first electrode layer;
a second electrode layer;
at least one structural templating layer disposed between the first and second electrodes; and
an organic functional layer disposed over the at least one structural templating layer,
wherein the functional layer has its molecules in an ordered molecular arrangement, wherein at least a majority of the molecules of the functional layer are in a non-preferential orientation with respect to the layer immediately below the at least one structural templating layer.

24. The device of claim 23, wherein at least 75% of the molecules of the functional layer are in the non-preferential orientation.

25. The device of claim 23, wherein the functional layer is an organic emissive layer.

26. The device of claim 25, wherein the organic emissive layer further comprising a host material and a dopant material and a majority of the molecules of the functional layer that are in the non-preferential orientation include both the host material and the dopant material.

27. The device of claim 23, wherein the functional layer is an organic hole transporting layer.

28. The device of claim 23, wherein the functional layer is an organic electron transporting layer.

29. The device of claim 23, wherein the at least one structural templating layer comprising a layer of 3,4,9,10-perylenetetracarboxylic dianhydride (PTCDA).

30. The device of claim 23, wherein the at least one structural templating layer comprising a layer of 3,4,9,10-perylenetetracarboxylic dianhydride (PTCDA) as a primary structural templating layer and a secondary structural templating layer deposited directly on the PTCDA layer.

31. The device of claim 30, wherein the secondary structural templating layer comprises another organic material having a perylene core, other than PTCDA.

32. The device of claim 31, wherein the another organic material having a perylene core is diindenoperylene.

33. The device of claim 31, wherein the secondary structural templating layer comprises highly-oriented pyrolytic graphite.

34. The device of claim 25, wherein the at least one structural templating layer comprising a layer of 3,4,9,10-perylenetetracarboxylic dianhydride (PTCDA) deposited directly on the first electrode layer as a primary structural templating layer and a secondary structural templating layer deposited directly on the PTCDA layer, wherein the secondary structural templating layer is an exciton blocking layer that confines excitons to the organic emissive layer.

35. An method for making an organic light emitting device comprising:
providing a first electrode layer;
providing a second electrode layer;
forming at least one structural templating layer disposed between the first and second electrodes; and
forming an organic functional layer disposed over the at least one structural templating layer,
wherein the functional layer has its molecules in an ordered molecular arrangement, wherein at least a majority of the molecules of the functional layer are in a non-preferential orientation with respect to the layer immediately below the at least one structural templating layer.

36. The method of claim 35, wherein the functional layer is an organic emissive layer.

37. The method of claim 35, wherein the organic emissive layer further comprising a host material and a dopant material and a majority of the molecules of the functional layer that are in the non-preferential orientation include both the host material and the dopant material.

38. The method of claim 35, wherein the functional layer is an organic hole transporting layer.

39. The method of claim 35, wherein the functional layer is an organic electron transporting layer.

40. The method of claim 35, wherein the at least one structural templating layer comprising a layer of 3,4,9,10-perylenetetracarboxylic dianhydride (PTCDA).

41. The method of claim 35, wherein the at least one structural templating layer comprising a layer of 3,4,9,10-perylenetetracarboxylic dianhydride (PTCDA) as a primary structural templating layer and a secondary structural templating layer deposited directly on the PTCDA layer.

42. The method of claim 41, wherein the secondary structural templating layer comprises another organic material having a perylene core, other than PTCDA.

43. The method of claim 42, wherein the another organic material having a perylene core is diindenoperylene.

44. The method of claim 41, wherein the secondary structural templating layer comprises highly-oriented pyrolytic graphite.

45. The method of claim 35, wherein the at least one structural templating layer comprising a layer of 3,4,9,10-perylenetetracarboxylic dianhydride (PTCDA) deposited directly on the first electrode layer as a primary structural templating layer and a secondary structural templating layer deposited directly on the PTCDA layer, wherein the secondary structural templating layer is an exciton blocking layer that confines excitons to the organic emissive layer.
